(19) United States
(12) Patent Application Publication
(10) Pub. No.: US 2013/0286612 A1
(43) Pub. Date: Oct. 31, 2013

(54) MOUNTING STRUCTURE FOR CIRCUIT COMPONENT AND METHOD FOR MOUNTING CIRCUIT COMPONENT

(71) Applicants: Tomoya Iwasaki, Osaka (JP); Hironori Konno, Osaka (JP)

(72) Inventors: Tomoya Iwasaki, Osaka (JP); Hironori Konno, Osaka (JP)

(73) Assignee: PANASONIC CORPORATION, Osaka (JP)

(21) Appl. No.: 13/996,419

(22) PCT Filed: Jan. 10, 2012
(86) PCT No.: PCT/JP2012/000070

§ 371 Date: Jun. 20, 2013

(30) Foreign Application Priority Data
Jan. 13, 2011 (JP) 2011-004690

(51) Int. Cl. H05K 1/18; H05K 3/30

(52) U.S. Cl. CPC H05K 1/181; H05K 3/301
USPC 361/760; 29/832

(57) ABSTRACT

In mounting a relatively large circuit component such as an electrolytic capacitor and a film capacitor on a circuit board, the present invention decreases a protruding height of the component beyond the board, preventing abnormal noise caused by making contact the component with the board. The circuit board has an opening or a notch in which the body of a circuit component to be mounted on the board is disposed, and a protrusion that protrudes from one or more sides of the opening or the notch. The component is disposed on the board in a manner that the body of the component is inserted through the opening or the notch and that the body has no contact with the board except for the protrusion. With the condition maintained, the protrusion and the body of the component are bonded together by fixing material for fixing the component to the board.

### TECHNICAL FIELD

The present invention relates to a mounting structure of a circuit component onto a circuit board used for electric equipment such as a plasma display apparatus, and also relates to a mounting method of a circuit component.

### BACKGROUND ART

An AC surface discharge panel as a typical plasma display panel (hereinafter, simply referred to as a “panel”) has a plurality of discharge cells between a front substrate and a rear substrate oppositely disposed to each other. On the glass front substrate, a plurality of display electrode pairs, each including a pair of a scan electrode and a sustain electrode, is arranged in parallel with each other. A dielectric layer and a protective layer are formed so as to cover the display electrode pairs.

On the glass rear substrate, a plurality of data electrodes is arranged in parallel with each other. A dielectric layer is formed so as to cover the data electrodes. On the dielectric layer, a plurality of barrier ribs is formed so as to be parallel with the data electrodes. A phosphor layer is formed on the surface of the dielectric layer and on the side surfaces of the barrier ribs.

The front substrate and the rear substrate are oppositely located in a manner that the display electrode pairs are positioned orthogonal to the data electrodes, and then the two substrates are sealed with each other. A discharge space formed in the sealed inside is filled with, for example, a discharge gas containing xenon at a partial pressure of 5%. Discharge cells are formed at which the display electrode pairs face the data electrodes. In the panel with the structure above, ultraviolet rays are generated by gas discharge in each discharge cell. The ultraviolet rays excite phosphors of the red (R) color, green (G) color, and blue (B) color so that light is emitted for the display of a color image.

A plasma display apparatus has a frame that is called “chassis” and is accommodated in the housing. The aforementioned panel and a driver circuit for driving the panel are attached to the chassis. The housing has is formed of a front frame and a back cover.

The thickness of a plasma display apparatus depends on the thickness of a panel, the thickness of circuit components forming the driver circuit, the mounting structure of the circuit components on the circuit board, and the like.

Although the panel has several millimeters of thickness, the plasma display apparatus contains a relatively large circuit component. To minimize the thickness of the plasma display apparatus, there have some suggestions for accommodating a relatively large circuit component in the thin housing (see patent literature 1, for example).

According to the mounting method disclosed in patent literature 1, an opening or a notch is formed in the circuit board so that a circuit component is fitted therein. That is, a circuit component is fitted in the opening or in the notch, by which the circuit component is attached to the circuit board. With the mounting method, fitting a circuit component in the opening or the notch decreases a protruding height of the circuit component beyond the circuit board.

In a plasma display apparatus, a circuit component mounted on the circuit board often has a vibration caused by vibrations occurred outside the plasma display apparatus. Particularly, a plasma display apparatus having a large screen—where the apparatus itself and the circuit boards have increase in size—is easily affected by vibrations occurred outside the plasma display apparatus. As a result, this develops a new problem that circuit components mounted on the circuit board easily vibrate.

Among others, in a plasma display apparatus with a built-in speaker, the increase in size further increases the tendency of the circuit components to vibrate. Of various circuit components, relatively large circuit components such as an electrolytic capacitor and a film capacitor often make contact with the opening or notch in which the circuit components are disposed. Therefore, when such a relatively large circuit component has vibrations and contacts with the circuit board, abnormal noise can occur.

### CITATION LIST

### Patent Literature

PTL1
Japanese Unexamined Utility Model Application Publication No. H05-093075

### SUMMARY OF THE INVENTION

The present invention relates to a mounting structure of a circuit component when the circuit component is mounted on a circuit board. The circuit board has an opening or a notch in which the body of a circuit component is fitted, and a protrusion that protrudes from one side or two-or-more sides of the opening or the notch. A circuit component is disposed on the circuit board in a manner that the body of the circuit component is inserted through the opening or the notch and that the body of the circuit component has no contact with the circuit board except for the protrusion. With the condition maintained, the body of the circuit component and the protrusion are bonded by fixing material applied to the protrusion so that the circuit component is fixed to the circuit board.

In mounting a relatively large circuit component such as an electrolytic capacitor and a film capacitor on a circuit board, the structure above decreases a protruding height of the component, preventing abnormal noise caused by making contact the circuit component with the circuit board.

Besides, in the mounting structure of a circuit component of the present invention, the opening or the notch is formed in the circuit board so as to be larger than the external dimensions of the body of the circuit component to be disposed in the opening or the notch.

According to the mounting structure of a circuit component of the present invention, the protrusion of the circuit board may be formed on a side of the opening or the notch, which side is orthogonal to another side along which a through-hole is formed for inserting a lead wire of the circuit component.

Further, according to the mounting structure of a circuit component of the present invention, the protrusion of the circuit board may be formed on a side of the opening or the notch, which side is opposite to another side along which a through-hole is formed for inserting a lead wire of the circuit component.

Still further, according to the mounting structure of a circuit component of the present invention, a plurality of circuit components may be disposed in the opening or the notch of the circuit board. And the opening or the notch may be formed in the circuit board so as to be larger than the dimensions of the plurality of circuit components, and the protrusions in the same number as the circuit components may be formed at the opening or the notch.

The present invention relates to a method of mounting a circuit component on a circuit board while the body of the circuit component is being inserted in an opening or a notch of the circuit board. The mounting method uses a pallet having a board holder for holding the circuit board at a predetermined height, two-or-more protrusions whose ends are higher than the board holder, and a component holder formed between the protrusions for holding a circuit component at a predetermined height. First, the circuit board is mounted on the pallet in such a manner that the protrusions are fitted in the opening or the notch of the circuit board. Next, a circuit component is mounted on the component holder. After that, a fixing material is applied to the protrusion formed at the opening or the notch so that the protrusion and the body of the circuit component are bonded together. The circuit component is thus fixed to the circuit board.

In mounting a relatively large circuit component such as an electrolytic capacitor and a film capacitor on the circuit board, the method above allows such a component to have decrease in a protruding height of the component beyond the circuit board, preventing abnormal noise caused by making contact the circuit component with the circuit board.

### BRIEF DESCRIPTION OF THE DRAWINGS

FIG. 1 is an exploded perspective view showing the structure of a panel for use in a plasma display apparatus in accordance with a first exemplary embodiment of the present invention.

FIG. 2 is an exploded perspective view schematically showing the structure of the plasma display apparatus in accordance with the first exemplary embodiment of the present invention.

FIG. 3 schematically shows a layout example of each circuit board forming a circuit board set of the plasma display apparatus in accordance with the first exemplary embodiment of the present invention.

FIG. 4A is a perspective view schematically showing an example of the mounting structure when a circuit component is mounted on a circuit board of the plasma display apparatus in accordance with the first exemplary embodiment of the present invention.

FIG. 4B schematically shows an example of the mounting structure when a circuit component is mounted on a circuit board of the plasma display apparatus in accordance with the first exemplary embodiment of the present invention.

FIG. 4C schematically shows an example of the mounting structure after the completion of mounting a circuit component on a circuit board of the plasma display apparatus in accordance with the first exemplary embodiment of the present invention.

FIG. 5A is a plan view showing an example of the opening formed in a circuit board of the plasma display apparatus in accordance with a second exemplary embodiment of the present invention.

FIG. 5B is a plan view schematically showing an example of the mounting structure after the completion of mounting an electrolytic capacitor on a circuit board of the plasma display apparatus in accordance with the second exemplary embodiment of the present invention.

FIG. 6A is a plan view showing an example of the notch formed in a circuit board of the plasma display apparatus in accordance with a third exemplary embodiment of the present invention.

FIG. 6B is a plan view schematically showing an example of the mounting structure after the completion of mounting an electrolytic capacitor on a circuit board of the plasma display apparatus in accordance with the third exemplary embodiment of the present invention.

FIG. 7A is a plan view showing an example of the opening formed in a circuit board of the plasma display apparatus in accordance with a fourth exemplary embodiment of the present invention.

FIG. 7B is a plan view schematically showing an example of the mounting structure after the completion of mounting a plurality of electrolytic capacitors on a circuit board of the plasma display apparatus in accordance with the fourth exemplary embodiment of the present invention.

FIG. 8A is a plan view showing an example of the opening formed in a circuit board of the plasma display apparatus in accordance with a fifth exemplary embodiment of the present invention.

FIG. 8B schematically shows an example of the mounting structure after the completion of mounting a film capacitor on a circuit board of the plasma display apparatus in accordance with the fifth exemplary embodiment of the present invention.

FIG. 9 schematically shows an example of the pallet on which a circuit board is mounted of the plasma display apparatus in accordance with a sixth exemplary embodiment of the present invention.

FIG. 10 schematically shows an example of the pallet on which a circuit board is mounted of the plasma display apparatus in accordance with a seventh exemplary embodiment of the present invention.

### DESCRIPTION OF EMBODIMENTS

Hereinafter, the mounting structure of a circuit component and the mounting method of a circuit component of the present invention will be described with reference to the accompanying drawings. In the description below, as an example, the present invention is used for a plasma display apparatus.

### First Exemplary Embodiment

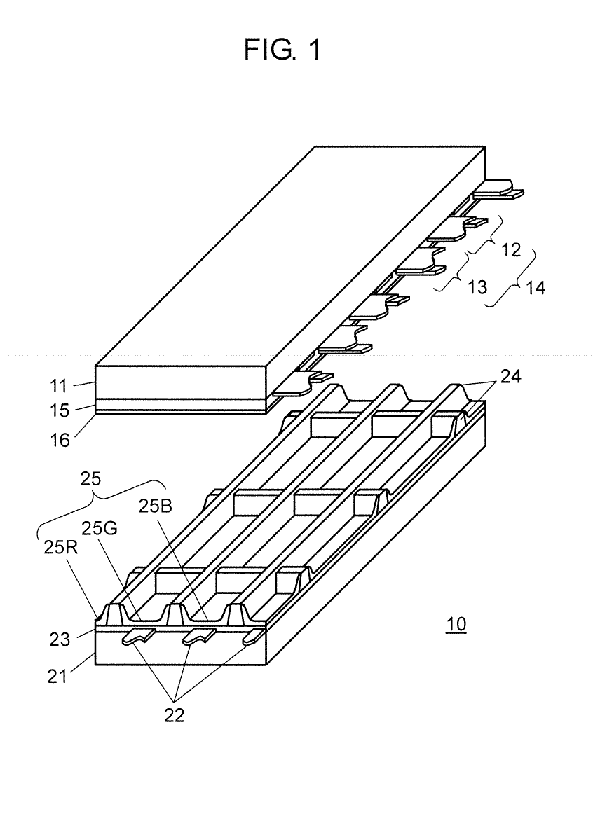

FIG. 1 is an exploded perspective view showing the structure of panel 10 for use in a plasma display apparatus in accordance with the first exemplary embodiment of the present invention.

A plurality of display electrode pairs 14, each including scan electrode 12 and sustain electrode 13, is formed on front substrate 11 made of glass. Dielectric layer 15 is formed so as to cover scan electrodes 12 and sustain electrodes 13. Protective layer 16 is formed over dielectric layer 15.

Protective layer 16 is made of a material predominantly composed of magnesium oxide (MgO). The MgO-based material is proven as being effective in decreasing a discharge start voltage in the discharge cells. Besides, the material offers a large coefficient of secondary electron emission and high durability against a gas of neon (Ne) xenon (Xe) used as discharge gas.

Protective layer 16 may be a single-layer structure or a multi-layer structure. Besides, protective layer 16 may be formed of a layer having particles thereon.

On rear substrate 21, a plurality of data electrodes 22 is formed in parallel. Insulator layer 23 is formed so as to cover data electrodes 22, and grid-like barrier ribs 24 are formed on insulator layer 23. On the side faces of barrier ribs 24 and on the surface of insulator layer 23, phosphor layer 25R for emitting light of red (R) color, phosphor layer 25G for emitting light of green (G) color, and phosphor layer 25B for emitting light of blue (B) color are formed. Hereinafter, phosphor layer 25R, phosphor layer 25G, and phosphor layer 25B are also referred to collectively as phosphor layers 25.

Front substrate 11 and rear substrate 21 are oppositely disposed such that display electrode pairs 14 intersect data electrodes 22 via small space, so that a discharge space is formed between front substrate 11 and rear substrate 21. The outer peripheries of the substrates are sealed with a sealing material such as a glass frit. The discharge space is filled with discharge gas, for example, a mixture gas of neon and xenon.

The discharge space is divided by barrier ribs 24 into a plurality of compartments. Discharge cells are formed in the intersecting parts of display electrode pairs 14 and data electrodes 22.

Discharge is generated in the discharge cells so as to excite phosphor layers 25 (i.e. so as to light on a discharge cell) for light emission, by which panel 10 has color image display.

Each size of front substrate 11 and rear substrate 21 is, for example, 980 mm×570 mm for a 42-inch panel. For a 60-inch panel, each substrate has a size of 1500 mm×870 mm, for example. Each of front substrate 11 and rear substrate 21 has a thickness of, for example, 1.8 mm.

In panel 10, one pixel is formed by three successive discharge cells arranged in the extending direction of display electrode pairs 14. The three discharge cells are a discharge cell (red discharge cell) having phosphor layer 25R for emitting light of red (R) color, a discharge cell (green discharge cell) having phosphor layer 25G for emitting light of green (G) color, and a discharge cell (blue discharge cell) having phosphor layer 25B for emitting light of blue (B) color.

The structure of panel 10 is not limited to the above, and may include barrier ribs formed into stripes extending in the vertical direction, for example.

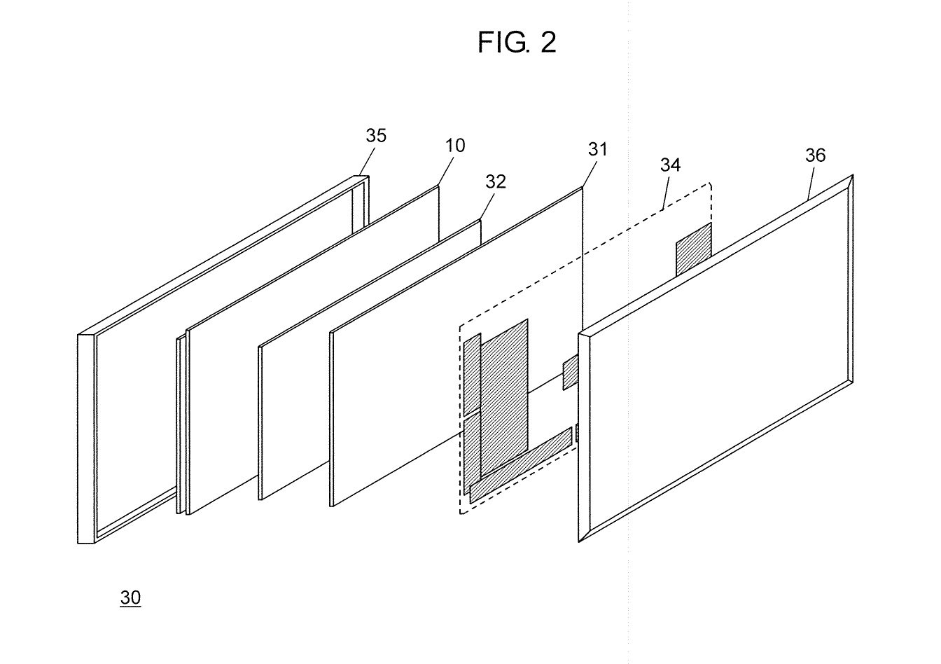

FIG. 2 is an exploded perspective view schematically showing the structure of plasma display apparatus 30 in accordance with the first exemplary embodiment of the present invention.

Plasma display apparatus 30 has panel 10, chassis 31, heat transfer sheet 32, circuit board set 34, front frame 35, and back cover 36.

Chassis 31 retains panel 10 so as to position the image display surface of panel 10 at the front of plasma display apparatus 30.

Heat transfer sheet 32 bonds panel 10 and chassis 31 together and transfers heat generated in panel 10 to chassis 31.

Circuit board set 34 is formed of the driver circuits for driving panel 10 and is disposed on the rear side of chassis 31.

Front frame 35 and back cover 36 accommodate panel 10, chassis 31, heat transfer sheet 32, and circuit board set 34. Plasma display apparatus 30 is thus structured.

Front frame 35 may contain a transparent protective plate for protecting panel 10. In the exemplary embodiment, instead of the protective plate, a protective sheet is directly attached to the surface of panel 10 to decrease the thickness of plasma display apparatus 30.

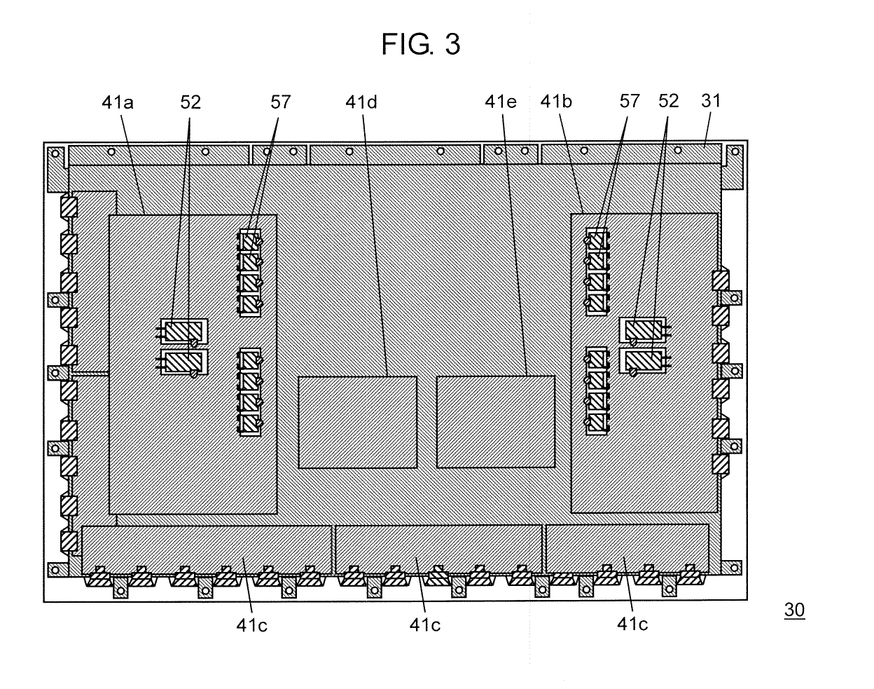

FIG. 3 schematically shows a layout example of each circuit board forming circuit board set 34 of plasma display apparatus 30 in accordance with the first exemplary embodiment of the present invention.

FIG. 3 is a plan view seen from the rear side of plasma display apparatus 30 with back cover 36 removed. It schematically shows the layout of the circuit boards of circuit board 41a, circuit board 41b, circuit board 41c, circuit board 41d, and circuit board 41e. In the description below, circuit board 41a, circuit board 41b, circuit board 41c, circuit board 41d, and circuit board 41e are also referred to collectively as circuit board 41. The driver circuits for driving plasma display apparatus 30, a signal processing circuit, and a power source circuit are mounted on circuit board 41.

FIG. 3 shows a layout example of each circuit board of plasma display apparatus 30 having panel 10 of 50-inch display size.

Circuit board 41a has a scan electrode driver circuit for generating driving voltage to be applied to scan electrodes 12.

Circuit board 41b has a sustain electrode driver circuit for generating driving voltage to be applied to sustain electrodes 13.

Circuit board 41c has a data electrode driver circuit for generating driving voltage to be applied to data electrodes 22.

Circuit board 41d has a signal processing circuit.

Circuit board 41e has a power source circuit.

Circuit board 41a, circuit board 41b, circuit board 41c, circuit board 41d, and circuit board 41e are fixed to chassis 31 so as to be parallel to chassis 31.

Electrolytic capacitor 52 and film capacitor 57, which are relatively large circuit component, are mounted on circuit board 41.

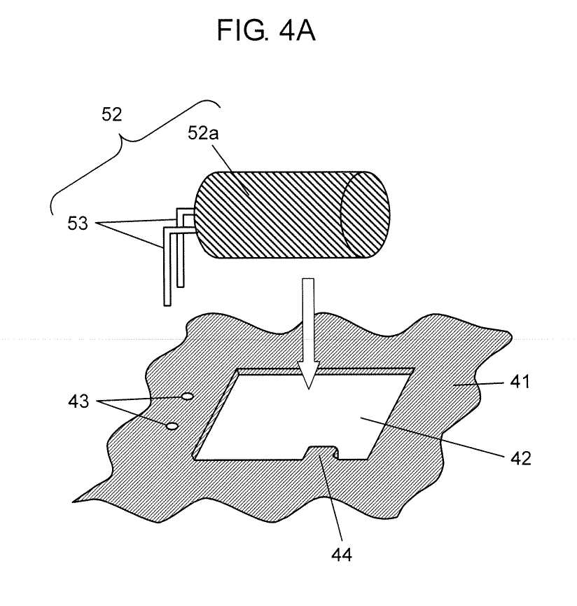

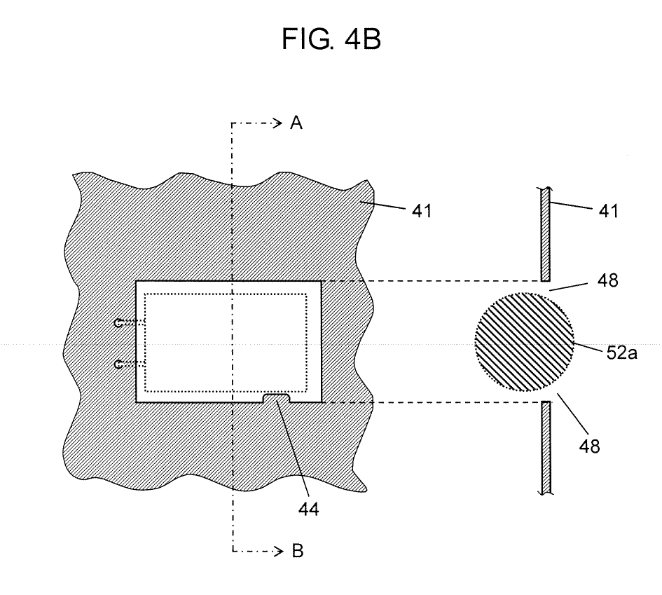

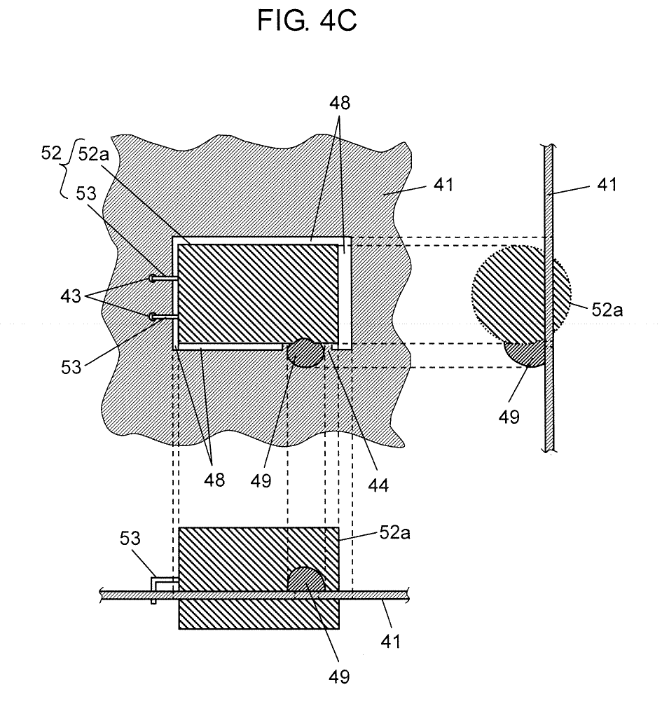

FIG. 4A is a perspective view schematically showing an example of the mounting structure when a circuit component is mounted on circuit board 41 of plasma display apparatus 30 in accordance with the first exemplary embodiment of the present invention.

FIG. 4B schematically shows an example of the mounting structure when a circuit component is mounted on circuit board 41 of plasma display apparatus 30 in accordance with the first exemplary embodiment of the present invention.

FIG. 4C schematically shows an example of the mounting structure after the completion of mounting a circuit component on circuit board 41 of plasma display apparatus 30 in accordance with the first exemplary embodiment of the present invention.

FIG. 4A, FIG. 4B, and FIG. 4C show details of the mounting structure when electrolytic capacitor 52 as a circuit component is mounted on circuit board 41. FIG. 4B schematically shows an example of the mounting structure in the plan view and the side view when a circuit component is mounted on circuit board 41. FIG. 4C schematically shows an example of the mounting structure after the completion of mounting a circuit component on circuit board 41 in the plan view and the side view.

As is shown in FIG. 4A, circuit board 41 has opening 42, through-hole 43, and protrusion 44.

Opening 42 is formed in circuit board 41 so as to have a size larger than the external dimensions of body 52a except for lead wire 53 of electrolytic capacitor 52 to be mounted on circuit board 41.

Through-hole 43 is formed in circuit board 41 so as to let lead wire 53 of electrolytic capacitor 52 through.

Protrusion 44 is formed on one side of opening 42 and has a shape protruding from the one side toward an opposite side.

Lead wire 53 of electrolytic capacitor 52 is inserted in through-hole 43 and then soldered to circuit board 41. Electrolytic capacitor 52 is thus electrically connected to an electric circuit formed on circuit board 41 and is fixed to circuit board 41.

Lead wire 53 is bent in advance. Inserting lead wire 53 in through-hole 43 allows body 52a of electrolytic capacitor 52 to be “inserted through” opening 42. Electrolytic capacitor 52 is thus disposed in opening 42.

Prior to the mounting, the position of through-hole 43 in circuit board 41 and the bend length of lead wire 53 are determined so that body 52a of electrolytic capacitor 52 has no contact with circuit board 41.

In the exemplary embodiment, aforementioned “inserted through” means the following state of electrolytic capacitor 52 positioned in opening 42. That is, the side surfaces of body 52a protrude not only beyond the top surface but also beyond the rear surface of circuit board 41.

Through-hole 43 is formed in circuit board 41 so that body 52a of electrolytic capacitor 52 has no contact with circuit board 41.

As is shown in the sectional view taken along the line A-B of FIG. 4B, electrolytic capacitor 52 is positioned in opening 42 so as to have clearance 48 between body 52a of electrolytic capacitor 52 and circuit board 41 except for protrusion 44.

In FIG. 4B, electrolytic capacitor 52 is shown by the broken lines.

With the condition above maintained, body 52a of electrolytic capacitor 52 is fixed to circuit board 41 by fixing material applied to protrusion 44. FIG. 4C illustrates the state in which electrolytic capacitor 52 is fixed to circuit board 41. That is, electrolytic capacitor 52 is fixed to circuit board 41 such that body 52a and protrusion 44 are bonded together by the fixing material.

The fixing material applied to protrusion 44 may be, for example, adhesive 49. In the present invention, however, the fixing material to be applied to protrusion 44 is not limited to adhesive 49. Other materials such as resin and silicone can be used as long as body 52a of electrolytic capacitor 52 can be bonded to protrusion 44 thereby.

As is shown in FIG. 4C, electrolytic capacitor 52 is retained by circuit board 41 through lead wire 53 soldered to circuit board 41 and a part of body 52a bonded to protrusion 44 by a fixing material (adhesive 49, for example). Other than the bonded sections above, electrolytic capacitor 52 has no contact with circuit board 41. That is, clearance 48 is formed between electrolytic capacitor 52 and circuit board 41 except for the bonded sections above.

Electrolytic capacitor 52, as described above, is mounted on circuit board 41 while body 52a is inserted through opening 42 formed in circuit board 41. The structure contributes to decrease in a protruding height of electrolytic capacitor 52 beyond circuit board 41 by the inserted-through amount of body 52a in opening 42.

Besides, according to the exemplary embodiment, electrolytic capacitor 52 is fixed to circuit board 41 at three points—two points at which lead wire 53 is soldered to through-hole 43 and one point at which body 52a is bonded to protrusion 44 by fixing material (for example, adhesive 49). And clearance 48 is formed between electrolytic capacitor 52 and circuit board 41. If circuit board 41 and electrolytic capacitor 52 have a vibration caused by vibrations occurred outside plasma display apparatus 30, the aforementioned structure prevents occurrence of abnormal noise due to making contact electrolytic capacitor 52 with circuit board 41.

Body 52a of electrolytic capacitor 52 may contact or may not contact with protrusion 44.

In the exemplary embodiment, electrolytic capacitor 52 is taken as an example of circuit components, but it is not limited to. In the present invention, the circuit component disposed in opening 42 is not limited to electrolytic capacitor 52.

### Second Exemplary Embodiment

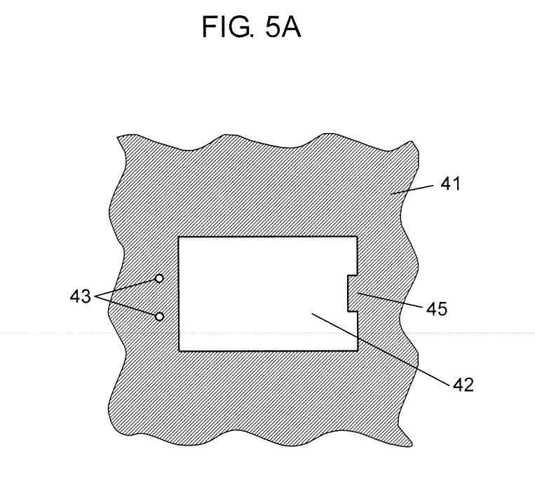

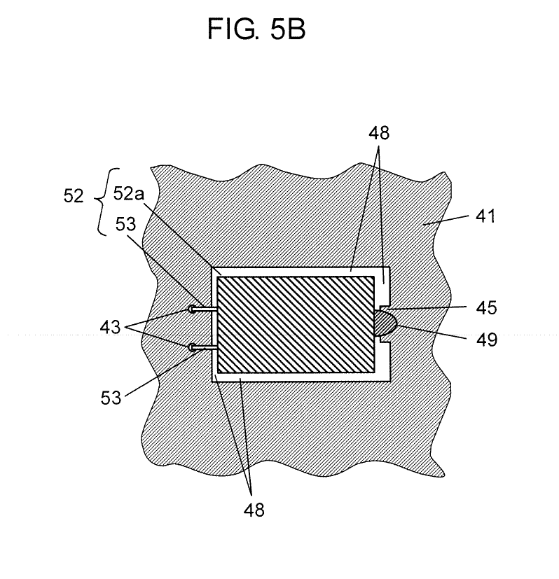

FIG. 5A is a plan view showing an example of opening 42 formed in circuit board 41 of plasma display apparatus 30 in accordance with the second exemplary embodiment of the present invention.

FIG. 5B is a plan view schematically showing an example of the mounting structure after the completion of mounting electrolytic capacitor 52 on circuit board 41 of plasma display apparatus 30 in accordance with the second exemplary embodiment of the present invention.

As is shown in FIG. 5A, circuit board 41 has opening 42, through-hole 43, and protrusion 45.

Opening 42 is formed in circuit board 41 so as to have a size larger than the external dimensions of body 52a except for lead wire 53 of electrolytic capacitor 52 to be mounted on circuit board 41.

Through-hole 43 is formed in circuit board 41 so as to let lead wire 53 of electrolytic capacitor 52 through.

Protrusion 45 is formed on one side of opening 42 and has a shape protruding from the one side toward an opposite side.

Whereas protrusion 44 of the first exemplary embodiment is formed on one side on a side of the lateral sides of body 52a, protrusion 45 is formed on a side on the top side of body 52a. The side on the top side of body 52a in opening 42 is the side which is opposite to the side of opening 42 where through-hole 43 is disposed. The one side on a side of the lateral sides of body 52a in opening 42 is a side of opening 42 which is orthogonal to the side where through-hole 43 is disposed.

Lead wire 53 of electrolytic capacitor 52 is inserted in through-hole 43 and then soldered to circuit board 41. Electrolytic capacitor 52 is thus electrically connected to an electric circuit formed on circuit board 41 and is fixed to circuit board 41.

Lead wire 53 is bent in advance. Inserting lead wire 53 in through-hole 43 allows body 52a of electrolytic capacitor 52 to be inserted through opening 42. Electrolytic capacitor 52 is thus disposed in opening 42.

Prior to the mounting, the position of through-hole 43 in circuit board 41 and the bend length of lead wire 53 are determined so that body 52a of electrolytic capacitor 52 has no contact with circuit board 41.

Electrolytic capacitor 52 is positioned in opening 42 so as to have clearance 48 between body 52a of electrolytic capacitor 52 and circuit board 41 except for protrusion 45.

With the condition above maintained, body 52a of electrolytic capacitor 52 is fixed to circuit board 41 by fixing material (for example, adhesive 49) applied to protrusion 45. FIG. 5B illustrates the state in which electrolytic capacitor 52 is fixed to circuit board 41. Electrolytic capacitor 52 is fixed to circuit board 41 such that body 52a and protrusion 45 are bonded together by fixing material (for example, adhesive 49).

As is shown in FIG. 5B, electrolytic capacitor 52 is retained by circuit board 41 through lead wire 53 soldered to circuit board 41 and a part of body 52a bonded to protrusion 45 by fixing material (adhesive 49, for example). Other than the bonded sections above, electrolytic capacitor 52 has no contact with circuit board 41. That is clearance 48 is formed between electrolytic capacitor 52 and circuit board 41 except for the bonded sections above.

Electrolytic capacitor 52, as described above, is mounted on circuit board 41 while body 52a is inserted through opening 42 formed in circuit board 41. The structure contributes to decrease in a protruding height of electrolytic capacitor 52 beyond circuit board 41 by the inserted-through amount of body 52a in opening 42.

Besides, according to the exemplary embodiment, electrolytic capacitor 52 is fixed to circuit board 41 at three points—two points at which lead wire 53 is soldered to through-hole 43 and one point at which body 52a is bonded to protrusion 44 by fixing material (for example, adhesive 49). And clearance 48 is formed between electrolytic capacitor 52 and circuit board 41. If circuit board 41 and electrolytic capacitor 52 have a vibration caused by vibrations occurred outside plasma display apparatus 30, the aforementioned structure prevents occurrence of abnormal noise due to making contact electrolytic capacitor 52 with circuit board 41.

The structure of the embodiment is similar to that of the first exemplary embodiment in that electrolytic capacitor 52 is fixed to circuit board 41 at the three points, with clearance 48 kept between electrolytic capacitor 52 and circuit board 41. However, according to the embodiment, forming protrusion 45 on an appropriate position allows the center of gravity of electrolytic capacitor 52 to be located inside the triangle having vertices of three points at which electrolytic capacitor 52 is fixed to circuit board 41. The structure above enhances stability of electrolytic capacitor 52 fixed to circuit board 41, so that it not only prevents occurrence of abnormal noise but also suppresses vibration itself of electrolytic capacitor 52.

Body 52a of electrolytic capacitor 52 may contact or may not contact with protrusion 45.

In the exemplary embodiment, electrolytic capacitor 52 is taken as an example of circuit components, but it is not limited to. In the present invention, the circuit component disposed in opening 42 is not limited to electrolytic capacitor 52.

### Third Exemplary Embodiment

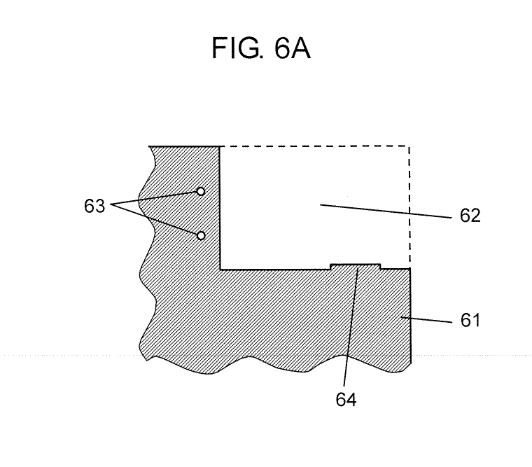

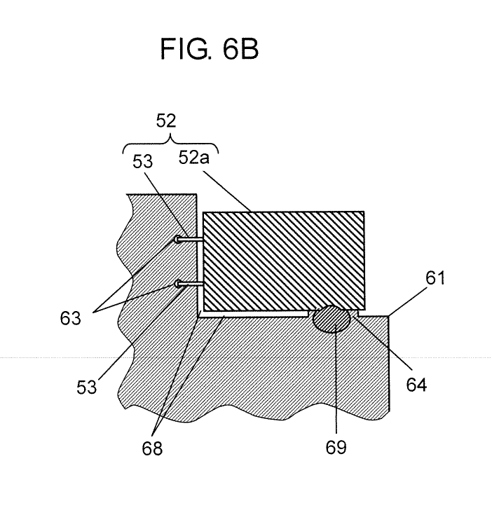

FIG. 6A is a plan view showing an example of notch 62 formed in circuit board 61 of plasma display apparatus 30 in accordance with the third exemplary embodiment of the present invention.

FIG. 6B is a plan view schematically showing an example of the mounting structure after the completion of mounting electrolytic capacitor 52 on circuit board 61 of plasma display apparatus 30 in accordance with the third exemplary embodiment of the present invention.

According to the third exemplary embodiment, as is shown in FIG. 6A, circuit board 61 has notch 62, through-hole 63, and protrusion 64.

Notch 62 is formed at a corner of circuit board 61 so as to have a size larger than the external dimensions of body 52a except for lead wire 53 of electrolytic capacitor 52 to be mounted on circuit board 61.

Opening 42 described in the first and the second exemplary embodiments has four sides closed by circuit board 41. In contrast, since formed at a corner of circuit board 61, notch 62 of the embodiment has two open sides corresponding to the two sides of opening 42. This is the difference between opening 42 and notch 62. In the embodiment, notch 62 is defined as the area surrounded by the two sides formed by circuit board 61 and two imaginary sides formed of two lines extended from two sides of circuit board 61. The two imaginary sides are shown by broken lines in FIG. 6A. Notch 62 is formed in circuit board 61 in a manner that the aforementioned area has a size larger than the external dimensions of the body of a circuit component (for example, body 52a) to be disposed in notch 62.

Notch 62 may be formed into a shape having three sides formed by circuit board 61 and one open side.

Through-hole 63 is formed in circuit board 61 so as to let lead wire 53 of electrolytic capacitor 52 through.

Protrusion 64 is formed on one side of notch 62 and has a shape protruding from the one side toward an opposite side (i.e., an imaginary side).

Lead wire 53 of electrolytic capacitor 52 is inserted in through-hole 63 and then soldered to circuit board 61. Electrolytic capacitor 52 is thus electrically connected to an electric circuit formed on circuit board 61 and is fixed to circuit board 61.

Lead wire 53 is bent in advance. Inserting lead wire 53 in through-hole 63 allows body 52a of electrolytic capacitor 52 to be inserted through notch 62. Electrolytic capacitor 52 is thus disposed in notch 62.

Prior to the mounting, the position of through-hole 63 in circuit board 61 and the bend length of lead wire 53 are determined so that body 52a of electrolytic capacitor 52 has no contact with circuit board 61.

Electrolytic capacitor 52 is positioned in notch 62 so as to have clearance 68 between body 52a of electrolytic capacitor 52 and circuit board 61 except for protrusion 64.

With the condition above maintained, body 52a of electrolytic capacitor 52 is fixed to circuit board 61 by fixing material (for example, adhesive 69) applied to protrusion 64. FIG. 6B illustrates the state in which electrolytic capacitor 52 is fixed to circuit board 61. Electrolytic capacitor 52 is fixed to circuit board 61 such that body 52a and protrusion 64 are bonded together by fixing material (for example, adhesive 69).

As is shown in FIG. 6B, electrolytic capacitor 52 is retained by circuit board 61 through lead wire 53 soldered to circuit board 61 and a part of body 52a bonded to protrusion 64 by fixing material (adhesive 69, for example). Other than the bonded sections above, electrolytic capacitor 52 has no contact with circuit board 61. That is, clearance 68 is formed between electrolytic capacitor 52 and circuit board 61 except for the bonded sections above.

Electrolytic capacitor 52, as described above, is mounted on circuit board 61 while body 52a is inserted through notch 62 formed in circuit board 61. The structure contributes to decrease in a protruding height of electrolytic capacitor 52 beyond the top surface of circuit board 61 by the inserted-through amount of body 52a in notch 62.

Besides, according to the exemplary embodiment, electrolytic capacitor 52 is fixed to circuit board 61 at three points—two points at which lead wire 53 is soldered to through-hole 63 and one point at which body 52a is bonded to protrusion 64 by fixing material (for example, adhesive 69). And clearance 68 is formed between electrolytic capacitor 52 and circuit board 61. If circuit board 61 and electrolytic capacitor 52 have a vibration caused by vibrations occurred outside plasma display apparatus 30, the aforementioned structure prevents occurrence of abnormal noise due to making contact electrolytic capacitor 52 with circuit board 61.

Body 52a of electrolytic capacitor 52 may contact or may not contact with protrusion 64.

In the exemplary embodiment, electrolytic capacitor 52 is taken as an example of circuit components, but it is not limited to. In the present invention, the circuit component disposed in notch 62 is not limited to electrolytic capacitor 52.

### Fourth Exemplary Embodiment

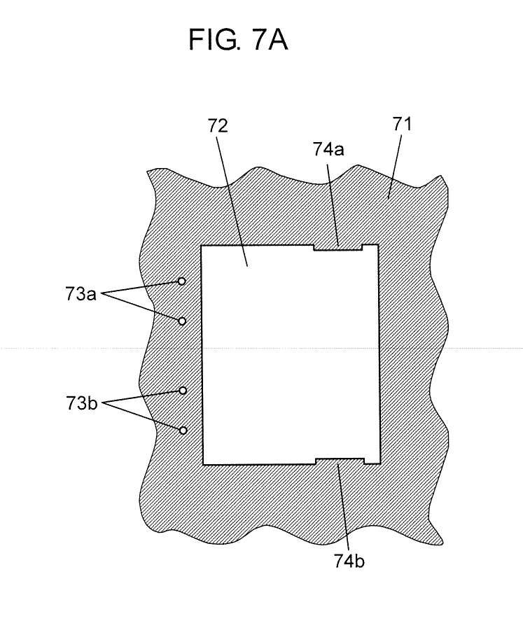

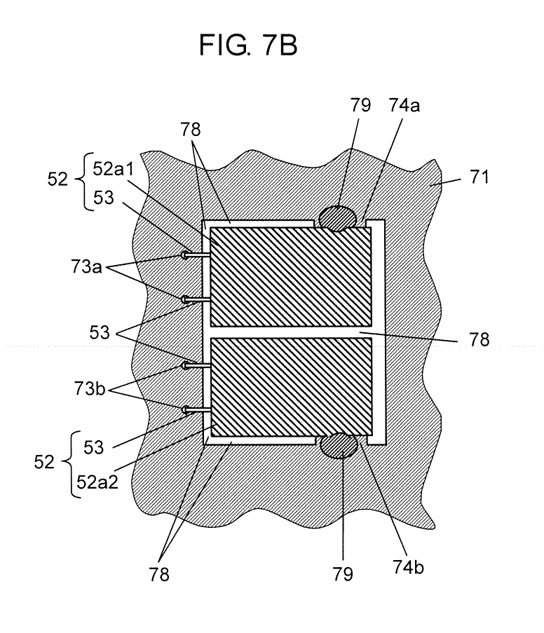

FIG. 7A is a plan view showing an example of opening 72 formed in circuit board 71 of plasma display apparatus 30 in accordance with the fourth exemplary embodiment of the present invention.

FIG. 7B is a plan view schematically showing an example of the mounting structure after the completion of mounting a plurality of electrolytic capacitors 52 on circuit board 71 of plasma display apparatus 30 in accordance with the fourth exemplary embodiment of the present invention.

As is shown in FIG. 7A, circuit board 71 has opening 72, through-hole 73a, through-hole 73b, protrusion 74a, and protrusion 74b.

Opening 72 is formed in circuit board 71 so as to have a size larger than the external dimensions of body 52a except for lead wire 53 of a plurality of electrolytic capacitors 52 (two capacitors, in the embodiment) to be mounted on circuit board 71.

Through-hole 73a, through-hole 73b are formed in circuit board 71 so as to let lead wire 53 of each of two electrolytic capacitors 52 through.

The number of through-hole 73 is determined so as to correspond to the number of electrolytic capacitor 52 to be disposed in opening 72.

Protrusion 74a is formed on one side of opening 72 and has a shape protruding from the one side toward an opposite side (for example, the side having protrusion 74b).

Protrusion 74b is formed on one side of opening 72 and has a shape protruding from the one side toward an opposite side (for example, the side having protrusion 74a).

Therefore, the sides having a protrusion of opening 72 are two in number.

Each lead wire 53 of two electrolytic capacitors 52 is inserted in through-hole 73a and through-hole 73b, and then soldered to circuit board 71. Each of two electrolytic capacitors 52 is thus electrically connected to an electric circuit formed on circuit board 71 and is fixed to circuit board 71.

Each lead wire 53 of two electrolytic capacitors 52 is bent in advance. Inserting each lead wire 53 of two electrolytic capacitors 52 in through-hole 73a and through-hole 73b allows each of body 52a1 and body 52a2 of two electrolytic capacitors 52 to be inserted through opening 72. Each of two electrolytic capacitors 52 is thus disposed in opening 72.

Prior to the mounting, the positions of through-hole 73a and through-hole 73b in circuit board 71 and the bend length of lead wire 53 are determined so that body 52a1 and body 52a2 of two electrolytic capacitors 52 have no contact with each other and with circuit board 71.

Each of two electrolytic capacitors 52 is positioned in opening 72 so as to have clearance 78 between body 52a1, body 52a2 of electrolytic capacitor 52 and circuit board 71 except for protrusion 74a and protrusion 74b.

With the condition above maintained, body 52a1 and body 52a2 of two electrolytic capacitors 52 are fixed to circuit board 71 by fixing material (for example, adhesive 79) applied to protrusion 74a and protrusion 74b. FIG. 7B illustrates the state in which two electrolytic capacitors 52 are fixed to circuit board 71. Two electrolytic capacitors 52 are fixed to circuit board 71 such that body 52a1 and protrusion 74a are bonded together by fixing material (for example, adhesive 79) and body 52a2 and protrusion 74b are bonded together by fixing material (for example, adhesive 79).

As is shown in FIG. 7B, each of two electrolytic capacitors 52 is retained by circuit board 71 through lead wire 53 soldered to circuit board 71, and a part of body 52a1 and body 52a2 bonded to protrusion 74a and protrusion 74b, respectively, by fixing material (adhesive 79, for example). Other than the bonded sections above, electrolytic capacitor 52 has no contact with circuit board 71. That is, clearance 78 is formed between two electrolytic capacitors 52 and circuit board 71, and between body 52a1 and body 52a2, except for the bonded sections above.

Two electrolytic capacitors 52, as described above, are mounted on circuit board 71 while body 52a1 and body 52a2 are inserted through opening 72 formed in circuit board 71. The structure contributes to decrease in a protruding height of each electrolytic capacitor 52 beyond the top surface of circuit board 71 by the inserted-through amount of body 52a1 and body 52a2 in opening 72.

Besides, according to the exemplary embodiment, each of two electrolytic capacitors 52 is fixed to circuit board 71 at three points—two points at which lead wire 53 is soldered to through-hole 73a and through-hole 73b and each one point at which body 52a is bonded to protrusion 74a and protrusion 74b by fixing material (for example, adhesive 79). And clearance 78 is formed between two electrolytic capacitors 52 and between electrolytic capacitor 52 and circuit board 71. If circuit board 71 and electrolytic capacitor 52 have a vibration caused by vibrations occurred outside plasma display apparatus 30, the aforementioned structure prevents occurrence of abnormal noise due to making contact electrolytic capacitor 52 with circuit board 71 and making contact electrolytic capacitors 52 with each other.

In the exemplary embodiment, two electrolytic capacitors 52 are taken as an example of the circuit components disposed in opening 72, but the circuit components disposed in opening 72 are not limited two in number; three or more circuit components may be disposed in opening 72. When three or more circuit components are disposed in opening 72, a medially-located circuit component cannot be fixed to protrusion 74a or protrusion 74b. In that case, as shown in FIG. 5A and FIG. 5B, the protrusions are formed on the side of the opening on the top side of each body of the circuit components so as to correspond in number to the circuit components, by which the circuit components are fixed to the protrusions by fixing material. In that case, the sides having a protrusion of opening 72 are three in number.

Body 52a1 and body 52a2 of each electrolytic capacitor 52 may contact or may not contact with protrusion 74a and protrusion 74b, respectively.

In the exemplary embodiment, electrolytic capacitor 52 is taken as an example of circuit components, but it is not limited to. In the present invention, the circuit component disposed in opening 72 is not limited to electrolytic capacitor 52.

### Fifth Exemplary Embodiment

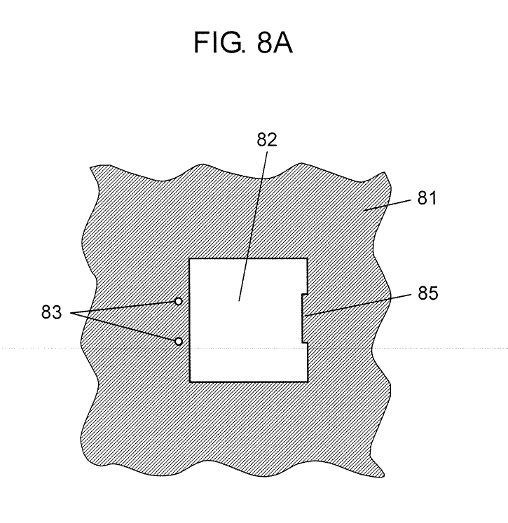

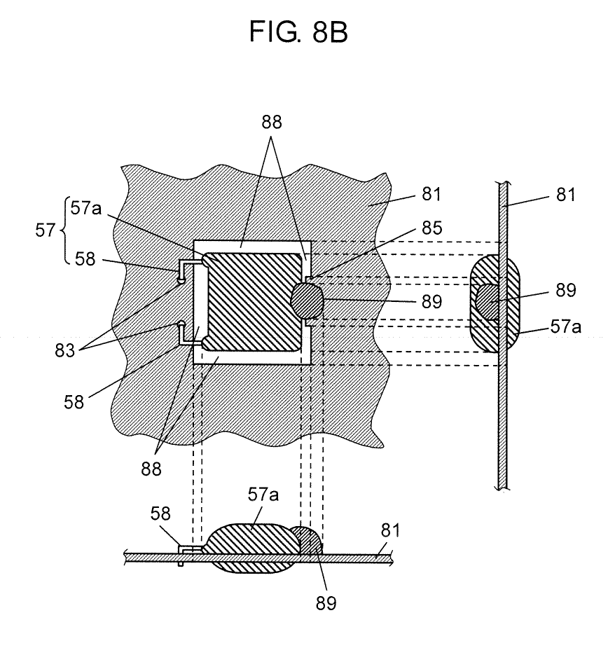

FIG. 8A is a plan view showing an example of opening 82 formed in circuit board 81 of plasma display apparatus 30 in accordance with the fifth exemplary embodiment of the present invention.

FIG. 8B is a plan view schematically showing an example of the mounting structure after the completion of mounting film capacitor 57 on circuit board 81 of plasma display apparatus 30 in accordance with the fifth exemplary embodiment of the present invention. FIG. 8B schematically shows an example of the mounting structure after the completion of mounting film capacitor 57 on circuit board 81 in the plan view and the side view.

As is shown in FIG. 8A, circuit board 81 has opening 82, through-hole 83, and protrusion 85.

Opening 82 is formed in circuit board 81 so as to have a size larger than the external dimensions of body 57a except for lead wire 58 of film capacitor 57 to be mounted on circuit board 81.

Through-hole 83 is formed in circuit board 81 so as to let lead wire 58 of film capacitor 57 through.

Protrusion 85 is formed on one side of opening 82 and has a shape protruding from the one side toward an opposite side.

Lead wire 58 of film capacitor 57 is inserted in through-hole 83 and then soldered to circuit board 81. Film capacitor 57 is thus electrically connected to an electric circuit formed on circuit board 81 and is fixed to circuit board 81.

Lead wire 58 is bent in advance. Inserting lead wire 58 in through-hole 83 allows body 57a of film capacitor 57 to be inserted through opening 82. Film capacitor 57 is thus disposed in opening 82.

Prior to the mounting, the position of through-hole 83 in circuit board 81 and the bend length of lead wire 58 are determined so that body 57a of film capacitor 57 has no contact with circuit board 81.

Film capacitor 57 is positioned in opening 82 so as to have clearance 88 between body 57a of film capacitor 57 and circuit board 81 except for protrusion 85.

With the condition above maintained, body 57a of film capacitor 57 is fixed to circuit board 81 by fixing material (for example, adhesive 89) applied to protrusion 85. FIG. 8B illustrates the state in which film capacitor 57 is fixed to circuit board 81. Film capacitor 57 is fixed to circuit board 81 such that body 57a and protrusion 85 are bonded together by fixing material (for example, adhesive 89).

As is shown in FIG. 8B, film capacitor 57 is retained by circuit board 81 through lead wire 58 soldered to circuit board 81 and a part of body 57a bonded to protrusion 85 by fixing material (adhesive 89, for example). Other than the bonded sections above, film capacitor 57 has no contact with circuit board 81. That is, clearance 88 is formed between film capacitor 57 and circuit board 81 except for the bonded sections above.

Film capacitor 57, as described above, is mounted on circuit board 81 while body 57a is inserted through opening 82 formed in circuit board 81. The structure contributes to decrease in a protruding height of film capacitor 57 beyond the top surface of circuit board 81 by the inserted-through amount of body 57a in opening 82.

Besides, according to the exemplary embodiment, film capacitor 57 is fixed to circuit board 81 at three points—two points at which lead wire 58 is soldered to through-hole 83 and one point at which body 57a is bonded to protrusion 85 by fixing material (for example, adhesive 89). And clearance 88 is formed between film capacitor 57 and circuit board 81. If circuit board 81 and film capacitor 57 have a vibration caused by vibrations occurred outside plasma display apparatus 30, the aforementioned structure prevents occurrence of abnormal noise due to making contact film capacitor 57 with circuit board 81.

Body 57a of film capacitor 57 may contact or may not contact with protrusion 85.

In the exemplary embodiment, film capacitor 57 is taken as an example of circuit components, but it is not limited to. In the present invention, the circuit component disposed in opening 82 is not limited to film capacitor 57.

### Sixth Exemplary Embodiment

In the exemplary embodiment, a method of mounting a circuit component on a circuit board will be described.

According to the embodiment, a dedicated pallet is used for positioning a circuit component at the opening or the notch shown in the first exemplary embodiment through the fifth exemplary embodiment and fixing the component to the circuit board. The circuit board is set on the pallet and then the circuit component is mounted on circuit board 91 so as to be located with the pallet.

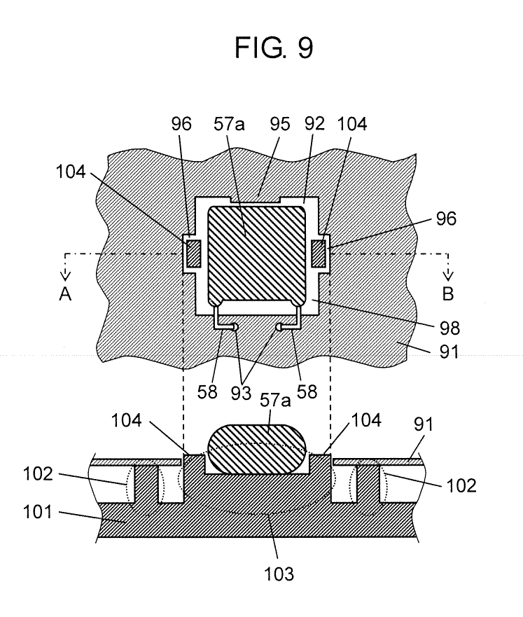

FIG. 9 schematically shows an example of pallet 101 on which circuit board 91 is mounted of plasma display apparatus 30 in accordance with the sixth exemplary embodiment of the present invention. In FIG. 9, an example of pallet 101 with circuit board 91 mounted thereon is schematically shown in the plan view and the sectional view. The sectional view of FIG. 9 shows the cross section taken along the line A-B of the plan view of FIG. 9.

As is shown in the sectional view of FIG. 9, pallet 101 has board holder 102, protrusion 104, and component holder 103.

Board holder 102 is formed so as to mount circuit board 91 thereon and holds circuit board 91 mounted on board holder 102 at a predetermined height.

In pallet 101, two protrusions 104 are formed for one opening 92. Each protrusion 104 is formed so as to be such location and size as to fit with the location and the size of opening 92 formed in circuit board 91 and fit with the location and the size of circuit component (film capacitor 57, for example) disposed in opening 92. Besides, protrusion 104 is formed so as to have the end thereof higher than that of board holder 102.

Component holder 103 is formed between two protrusions 104 disposed for a single opening, and holds the circuit component (film capacitor 57, for example) at a predetermined height.

Hereinafter, the procedures of mounting a circuit component on circuit board 91 will be described.

First, circuit board 91 is mounted on pallet 101 in such a way that two protrusions 104 fit in opening 92 of circuit board 91.

Circuit board 91 may contain two depressions 96 that fit with each of two protrusions 104. In that case, two protrusions 104 are formed on pallet 101 so as to fit with the location and the size of each of two depressions 96. Circuit board 91 is mounted on pallet 101 in such a way that each of two protrusions 104 fits with each of two depressions 96.

When depressions 96 are not formed in circuit board 91, protrusions 104 are formed so as to fit in the opening at a position slightly shorter than the side of the opening formed in circuit board 91. Circuit board 91 is mounted on pallet 101 so as to fit two protrusions 104 in the opening.

Next, lead wire 58 of the circuit component (film capacitor 57, for example) is inserted in through-hole 93 formed in circuit board 91. Lead wire 58 is bent in advance. Inserting lead wire 58 in through-hole 93 allows the body of the circuit component (film capacitor 57, for example) to be mounted on component holder 103 formed between two protrusions 104.

Component holder 103 is formed so as to have a height capable of holding the inserted-through amount of the body of the circuit component (film capacitor 57, for example) in opening 92. With the structure above, the circuit component is held in the condition in which its body is inserted through opening 92.

In addition, the circuit component (film capacitor 57, for example) is mounted on component holder 103 so as to have clearance 98 between the body and circuit board 91.

Next, fixing material (adhesive, for example) is applied to protrusion 95 of circuit board 91 for bonding the body of the circuit component (film capacitor 57, for example) and protrusion 95 together. The circuit component is thus fixed to circuit board 91.

As for other circuit components to be fixed to the circuit board, in a way similar to above, they are mounted on the corresponding component holders of pallet 101 and fixed to circuit board 91 by fixing material (adhesive, for example).

After the completion of fixing the circuit components to circuit board 91, circuit board 91 is removed from pallet 101. Circuit board 91 with the circuit components fixed thereon undergoes dip soldering in a solder bath, so that the circuit components are soldered to circuit board 91.

As described above, in the exemplary embodiment, forming protrusions 104 and component holder 103 on pallet 101 allows a circuit component to be mounted on the circuit board with a clearance kept around the circuit component in positioning the circuit component in the opening formed in the circuit board. Besides, the circuit components can be mounted on the circuit board with the components inserted through the opening. The structure contributes to decrease in a protruding height of the circuit component beyond the top surface of the circuit board by the inserted-through amount of the body disposed in the opening.

In the exemplary embodiment, film capacitor 57 is taken as an example of circuit components, but it is not limited to. In the present invention, the circuit component disposed in opening 92 is not limited to film capacitor 57. Other circuit components can be mounted on the circuit board in a similar way to above.

### Seventh Exemplary Embodiment

In the exemplary embodiment, a mounting method of a plurality of circuit components disposed in one opening of a circuit board will be described. The description below is given on an example in which two circuit components are disposed in one opening.

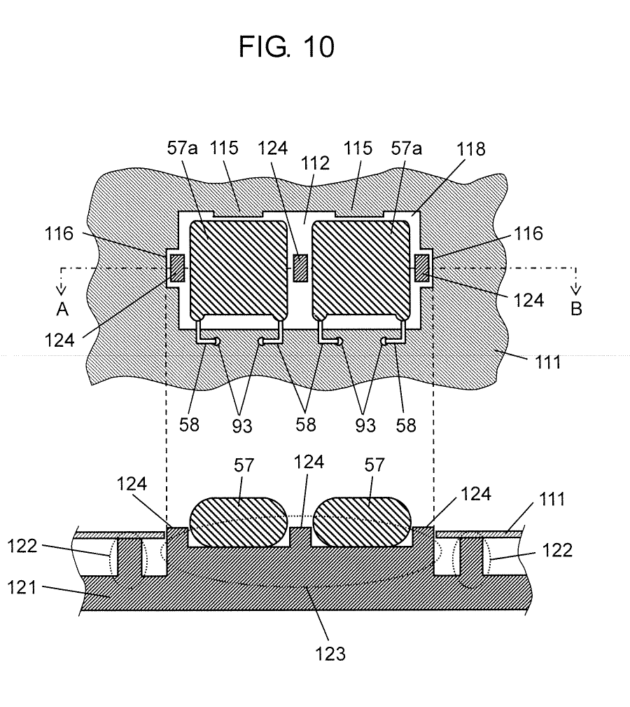

FIG. 10 schematically shows an example of pallet 121 on which circuit board 111 is mounted of plasma display apparatus 30 in accordance with the seventh exemplary embodiment of the present invention. In FIG. 10, an example of pallet 121 with circuit board 111 mounted thereon is schematically shown in the plan view and the sectional view. The sectional view of FIG. 10 shows the cross section taken along the line A-B of the plan view of FIG. 10.

As is shown in the sectional view of FIG. 10, pallet 121 has board holder 122, protrusion 124, and component holder 123.

Board holder 122 is formed so as to mount circuit board 111 thereon and holds circuit board 111 mounted on board holder 122 at a predetermined height.

In pallet 121, three protrusions 124 are formed for one opening 112. Each protrusion 124 is formed so as to be such location and size as to fit with the location and the size of opening 112 formed in circuit board 111 and fit with the location and the size of circuit components (two film capacitors 57, for example) disposed in opening 112. Besides, protrusion 124 is formed so as to have the end thereof higher than that of board holder 122.

Component holder 123 is formed between three protrusions 124 disposed for a single opening, and holds the circuit components (two film capacitors 57, for example) at a predetermined height.

Hereinafter, the procedures of mounting circuit components on circuit board 111 will be described.

First, circuit board 111 is mounted on pallet 121 in such a way that three protrusions 104 fit in opening 112 of circuit board 111.

Circuit board 111 may contain two depressions 116 that fit with each of two protrusions 124 (i.e., of three protrusions 124, the two protrusions at both ends). In that case, two protrusions 124 (located at both ends in three protrusions 124) are formed on pallet 121 so as to fit with the location and the size of each of two depressions 116. Circuit board 111 is mounted on pallet 121 in such a way that each of two protrusions 124 fits with each of two depressions 116.

When depressions 116 are not formed in circuit board 111, two protrusions 124 (located at both ends in three protrusions 124) are formed so as to fit in the opening at a position slightly shorter than the side of the opening formed in circuit board 111. Circuit board 111 is mounted on pallet 121 so as to fit two protrusions 124 in the opening.

Next, lead wire 58 of a circuit component (film capacitor 57, for example) is inserted in through-hole 93 formed in circuit board 111. Lead wire 58 is bent in advance. Inserting lead wire 58 in through-hole 93 allows the body of the circuit component (film capacitor 57, for example) to be mounted on component holder 123 formed between three protrusions 124.

Component holder 123 is formed so as to have a height capable of holding the inserted-through amount of each body of the circuit components (two film capacitors 57, for example) in opening 112. With the structure above, the circuit components are held in the condition in which their bodies are inserted through opening 112.

In addition, the circuit components (two film capacitors 57, for example) are mounted on component holder 123 so as to have clearance 118 between each body and circuit board 111.

One protrusion 124 (located in the middle of three protrusions 124) is formed into a size and a position sandwiched between the two circuit components (film capacitors 57, for example). The structure above allows the two circuit components to be retained with clearance 118 kept between the circuit components.

Next, fixing material (adhesive, for example) is applied to two protrusions 115 of circuit board 111 for bonding the bodies of the two circuit components (two film capacitors 57, for example) and two protrusions 115 together. The circuit components are thus fixed to circuit board 111.

As for other circuit components to be fixed to the circuit board, in a way similar to above, they are mounted on the corresponding component holders of pallet 121 and fixed to circuit board 111 by fixing material (adhesive, for example).

After the completion of fixing the circuit components to circuit board 111, circuit board 111 is removed from pallet 121. Circuit board 111 with the circuit components fixed thereon undergoes dip soldering in a solder bath, so that the circuit components are soldered to circuit board 111.

As described above, in the exemplary embodiment, forming protrusions 124 and component holder 123 on pallet 121 allows circuit components to be mounted on the circuit board with a clearance kept around the circuit components and between the circuit components in positioning the circuit components in the opening formed in the circuit board. Besides, the circuit components can be mounted on the circuit board with the components inserted through the opening. The structure contributes to decrease in a protruding height of the circuit components beyond the top surface of the circuit board by the inserted-through amount of the body disposed in the opening.

In the exemplary embodiment, film capacitor 57 is taken as an example of circuit components, but it is not limited to. In the present invention, the circuit component disposed in the opening is not limited to film capacitor 57. Other circuit components can be mounted on the circuit board in a similar way to above.

The description of the exemplary embodiment shows an example in which two circuit components are disposed in one opening. According to the present invention, however, the circuit components disposed in one opening is not limited to two in number; three or more circuit components may be disposed in one opening. When three or more circuit components are disposed in one opening, the protrusion and the component holder are formed so as to correspond in number to the circuit components disposed in one opening. For example, for three circuit components disposed in one opening, the pallet needs four protrusions and the component holder having three component-holding surfaces; and for four circuit components disposed in one opening, the pallet needs five protrusions and the component holder having four component-holding surfaces.

Although the description in the exemplary embodiments (of first exemplary embodiment through seventh exemplary embodiment) is given on a mounting structure of a circuit component on a circuit board and a mounting method of the circuit component in a plasma display apparatus as an example, the present invention is not limited to a plasma display apparatus. The mounting structure of a circuit component and the mounting method of a circuit component of the present invention are equally applicable with the same advantages to other electrical devices.

The specific numerical values shown in the exemplary embodiments of the present invention are set based on the characteristics of panel 10 that has a 50-inch screen and 1024 display electrode pairs 14, and simply show examples in the exemplary embodiments. The present invention is not limited to these numerical values. Preferably, each numerical value is set optimally for the characteristics of the panel, the specifications of the plasma display apparatus, or the like. Variations are allowed for each numerical value within the range in which the above advantages can be obtained.

### INDUSTRIAL APPLICABILITY

In mounting a circuit component on a circuit board, the present invention allows a relatively large circuit component such as an electrolytic capacitor and a film capacitor to have decrease in a protruding height of the component beyond the circuit board. And the structure of the present invention prevents abnormal noise caused by making contact the circuit component with the circuit board. The mounting structure of a circuit component and a mounting method of a circuit component of the present invention are therefore useful when a circuit component is mounted on electric equipment, particularly, on a flat display device.

### REFERENCE MARKS IN THE DRAWINGS

10 panel
11 front substrate
12 scan electrode
13 sustain electrode
14 display electrode pair
15 dielectric layer
16 protective layer
21 rear substrate
22 data electrode
23 insulator layer
24 barrier rib
25, 25R, 25G, 25B phosphor layer
30 plasma display apparatus
31 chassis
32 heat transfer sheet
34 circuit board set
35 front frame
36 back cover
41, 41a, 41b, 41c, 41d, 41e, 61, 71, 81, 91, 111 circuit board
42, 72, 82, 92, 112 opening
43, 63, 73a, 73b, 83, 93 through-hole
44, 45, 64, 74a, 74b, 75, 85, 95, 115 protrusion
48, 68, 78, 88, 98, 118 clearance
49, 69, 79, 89 adhesive
52 electrolytic capacitor
52a, 52a1, 52a2, 57a body
53, 58 lead wire
57 film capacitor
62 notch
96, 116 depression
101, 121 pallet
102, 122 board holder
103, 123 component holder
104, 124 protrusion

1. A mounting structure of a circuit component in mounting the circuit component on a circuit board,
wherein, the circuit board has an opening or a notch in which a body of a circuit component to be mounted on the circuit board is disposed, and a protrusion having a shape protruding from one side or two-or-more sides of the opening or the notch,
the circuit component is disposed on the circuit board in a manner that the body of the circuit component is inserted through the opening or the notch and that the body of the circuit component has no contact with the circuit board except for the protrusion, and the body of the circuit component and the protrusion are bonded by fixing material applied to the protrusion so that the circuit component is fixed to the circuit board.

2. The mounting structure of a circuit component of claim 1, wherein the opening or the notch is formed in the circuit board so as to be larger than external dimensions of the body of the circuit component to be disposed in the opening or the notch.

3. The mounting structure of a circuit component of claim 1, wherein the protrusion is formed on a side of the opening or the notch, which side is orthogonal to another side along which a through-hole is formed for inserting a lead wire of the circuit component to be disposed in the opening or the notch.

4. The mounting structure of a circuit component of claim 1, wherein the protrusion is formed on a side of the opening or the notch, which side is opposite to another side along which a through-hole is formed for inserting a lead wire of the circuit component to be disposed in the opening or the notch.

5. The mounting structure of a circuit component of claim 1, wherein a plurality of circuit components is disposed in the opening or the notch, and the opening or the notch is formed in the circuit board so as to be larger than dimensions of the plurality of circuit components, and the protrusions in the same number as the circuit components are formed at the opening or the notch.

6. A mounting method of a circuit component to be mounted on a circuit board having an opening or a notch with a body of the circuit component inserted through the opening or the notch, the method comprising:
preparing a pallet having a board holder for holding the circuit board at a predetermined height, two-or-more protrusions whose ends are higher than the board holder, and a component holder formed between the protrusions for holding the circuit component at a predetermined height;
mounting the circuit board on the pallet in such a manner that the protrusions are fitted in the opening or the notch of the circuit board;
mounting the circuit component on the component holder; and
applying fixing material to the protrusions formed at the opening or the notch so that the protrusions and the body of the circuit component are bonded together and the circuit component is fixed to the circuit board.
